(19) United States
(12) Patent Application Publication
(10) Pub. No.: US 2024/0112980 A1
(43) Pub. Date: Apr. 4, 2024

(54) Electromagnetic Interference Shielding and Sealing for Spring Screw Mounted Assemblies

(71) Applicant: NIO Technology (Anhui) Co., Ltd., Hefei, Anhui (CN)

(72) Inventors: Mohammad Reza Danesh Kadivar, San Jose, CA (US); Mehdi Rezaeisaray, San Jose, CA (US); Rogelio Ramos, San Jose, CA (US); Tommy Yuet Wong, San Jose, CA (US)

(73) Assignee: NIO Technology (Anhui) Co., Ltd., Hefei, Anhui (CN)

(21) Appl. No.: 18/468,560

(22) Filed: Sep. 15, 2023

Related U.S. Application Data
(60) Provisional application No. 63/407,451, filed on Sep. 16, 2022.
(60) Provisional application No. 63/414,838, filed on Oct. 10, 2022.

(51) Int. Cl. H01L 23/40; H05K 9/00

(52) U.S. Cl. CPC H01L 23/4006; H05K 9/0016; H05K 9/0081; H01L 2023/4087

(57) ABSTRACT

An electronics package includes a spring screw mounted assembly with a screw, a spring, a washer, electromagnetic shielding, and a seal. The seal is operable to prevent fluids or particulates from entering into the electronics package at the location where the screw engages with an enclosure forming the exterior of the electronics package. The electromagnetic shielding is operable to prevent electromagnetic interference or emission through the bore opening on the enclosure. The spring is operable to provide a controllable accurate load between processing units and the enclosure, to ensure sufficient or minimum thermal contact between components of the electronics package including the enclosure and processing units housed within the enclosure. The electronics package can include a stiffener that is operable to engage with the screw, where the stiffener is positioned proximate to the processing units.

### CROSS-REFERENCE TO RELATED APPLICATIONS

The present application claims the benefit of and priority, under 35 U.S.C. § 119(e), to U.S. Provisional Application Ser. No. 63/414,838, filed on Oct. 10, 2022, entitled “EMI/WATER SEALING FOR SPRING SCREW MOUNTED ASSEMBLIES,” and to U.S. Provisional Application Ser. No. 63/407,451, filed on Sep. 16, 2022, entitled “EMI/WATER SEALING FOR SPRING SCREW MOUNTED ASSEMBLIES,” the entire disclosures of which are hereby incorporated herein by reference, in their entirety, for all that they teach and for all purposes.

### FIELD OF THE DISCLOSURE

The present disclosure is generally directed to electronic packaging and, in particular, towards electromagnetic interference shielding and sealing for spring screw mounted assemblies.

### BACKGROUND

Modern electronic component assemblies or electronics packages such as printed circuit board assemblies may include one or multiple processing units (e.g., microprocessors, chips, integrated circuits, system on chips (SOCs), or the like) on a printed circuit board (PCB) or other circuit substrate. Many electronic component assemblies generate heat while in use, including by the flow of electric current through one or more resistive elements and/or components such as the processing units in the assemblies. When the heat generated by these elements and/or components is not efficiently removed, the temperatures of an electronic device can exceed a normal operating range. Operating electronics at temperatures outside of the normal operating range, even periodically, can cause premature failures and result in shorter component life spans. The efficient thermal management of electronic components and devices generally requires one or more cooling systems/elements. For example, the heat generated may be routed to, and/or dissipated into, a surrounding environment.

Select builds of the modern electronic component assemblies may be spring screw mounted assemblies, or assemblies that include spring-loaded screws operable to impart an accurate controllable load to the processing unit against the heatsink. For example, the spring-loaded screws may provide a force that ensures contact between processing components and a heatsink/coldplate or between a processing component and an enclosure. In some instances, where the processing component is heat-generating, the force may be used to ensure at least minimal contact is maintained between the processing component and the enclosure including with an intermediate thermal interfacing such as a thermal grease or paste.

Due to device size constraints, the screw and spring may need to be outside of the enclosure, thus requiring pass-through apertures into the enclosure. In certain environments, the spring screw mounted assemblies may be susceptible to electromagnetic interference and/or leakage including fluids and/or particulates. In particular, the assemblies may be susceptible to leakage through the screw holes within the enclosure that forms the exterior of the assembly. In addition, the assemblies may be susceptible to electromagnetic interference from other components or assemblies positioned proximate to the assemblies.

### BRIEF SUMMARY

Example aspects of the present disclosure include:

A spring screw mounted assembly for electromagnetic interference shielding and sealing of an electronics package comprises a screw including a head and a shaft, an electromagnetic interference (EMI) shielding element positioned between the head of the screw and the enclosure, a seal positioned between the head of the screw and the enclosure, and a washer positioned between the head of the screw and the enclosure. The shaft is operable to be inserted into a bore of an enclosure of the electronics package. The EMI shielding element is operable to prevent electromagnetic interference from passing through the bore of the enclosure to a processing unit housed within the enclosure. The seal is operable to prevent at least one of a fluid or particulates from passing through the bore of the enclosure to the processing unit housed within the enclosure. The shaft of the screw is at least partially surrounded by the washer, the EMI shielding element, and the seal when the shaft of the screw is inserted into the bore of the enclosure.

Any of the aspects herein, further comprising a spring operable to provide a force against the enclosure. The shaft of the screw is operable to be inserted through the spring and into the bore of the enclosure. The spring is positioned between the head of the screw and the washer. The washer is operable to transmit the force applied by the spring against at least a portion of the enclosure.

Any of the aspects herein, wherein the EMI shielding element is positioned between the washer and the enclosure. The seal is positioned between the EMI shielding element and the enclosure.

Any of the aspects herein, wherein the washer and the EMI shielding element are operable to fit within a first cut-out having a first diameter and a first depth in a surface in the enclosure. The seal is operable to fit within a second cut-out having a second diameter that is smaller than the first diameter and a second depth that is lower than the first depth in the surface of the enclosure.

Any of the aspects herein, wherein the seal is press-fit into the enclosure and operable to engage the shaft of the screw with an interference fit to prevent the at least one of a fluid or particulates from passing through the bore of the enclosure to the processing unit housed within the enclosure.

Any of the aspects herein, wherein the washer, the EMI shielding element, and the seal include co-axially aligned apertures through which the shaft of the screw passes through when the shaft is inserted into the bore of the enclosure.

Any of the aspects herein, wherein the shaft of the screw includes at least a first shaft section and a second shaft section.

Any of the aspects herein, wherein the first shaft section includes a first shaft diameter that corresponds to a first bore diameter of the bore. The second shaft section includes a second shaft diameter that is less than the first shaft diameter and that corresponds to a second bore diameter of a second bore, wherein the second bore diameter is less than the first bore diameter.

An electronics package comprises an enclosure, a processing unit housed within the enclosure, and a spring screw mounted assembly for electromagnetic interference shielding and sealing. The spring screw mounted assembly comprises a screw including a head and a shaft, an electromagnetic interference (EMI) shielding element positioned between the head of the screw and the enclosure, a seal positioned between the head of the screw and the enclosure, and a washer positioned between the head of the screw and the enclosure. The shaft is operable to be inserted into a bore of the enclosure. The EMI shielding element is operable to prevent electromagnetic interference from passing through the bore of the enclosure to the processing unit. The seal is operable to prevent at least one of a fluid or particulates from passing through the bore of the enclosure to the processing unit. The shaft of the screw is at least partially surrounded by the washer, the EMI shielding element, and the seal when the shaft of the screw is inserted into the bore of the enclosure.

Any of the aspects herein, wherein the enclosure further comprises a housing and a stiffener operable to uniformly distribute a force to the processing unit, where the stiffener includes threading that corresponds to threading of the shaft. The shaft is operable to be inserted into a bore of the housing into a printed circuit board (PCB), and the threading on the shaft is operable to engage with the threading on the stiffener after insertion into the bore of the housing and the PCB.

Any of the aspects herein, further comprising a spring operable to provide the force against the housing. The shaft of the screw is operable to be inserted through the spring and into the bore of the housing. The spring is positioned between the head of the screw and the washer. The washer is operable to transmit the force applied by the spring against at least a portion of the housing.

Any of the aspects herein, wherein the EMI shielding element is positioned between the washer and the housing. The seal is positioned between the EMI shielding element and the housing.

Any of the aspects herein, wherein the washer and the EMI shielding element are operable to fit within a first cut-out having a first diameter and a first depth in a surface in the housing. The seal is operable to fit within a second cut-out having a second diameter that is smaller than the first diameter and a second depth that is lower than the first depth in the surface of the housing.

Any of the aspects herein, wherein the seal is press-fit into the upper housing and operable to engage the shaft of the screw with an interference fit to prevent the at least one of a fluid or particulates from passing through the bore of the upper housing to the processing unit.

Any of the aspects herein, wherein the washer, the EMI shielding element, and the seal include co-axially aligned apertures through which the shaft of the screw passes through when the shaft is inserted into the bore of the housing.

Any of the aspects herein, wherein the shaft of the screw includes at least a first shaft section and a second shaft section.

Any of the aspects herein, wherein the first shaft section includes a first shaft diameter that corresponds to a first section of the bore having a first bore diameter. The second shaft section includes a second shaft diameter that is less than the first shaft diameter and that corresponds to a second section of the bore having a second bore diameter that is less than the first bore diameter.

A method for constructing an electronics package including a spring screw mounted assembly, comprising positioning a seal on an enclosure of the electronics package, positioning an electromagnetic interference (EMI) shielding element on the enclosure, positioning a washer on the enclosure, and inserting a screw including a head and a shaft into a bore of the enclosure. The washer is positioned between the head of the screw and the enclosure. The EMI shielding element is positioned between the head of the screw and the enclosure. The EMI shielding element is operable to prevent electromagnetic interference from passing through the bore of the enclosure to a processing unit housed within the enclosure. The seal is positioned between the head of the screw and the enclosure. The seal is operable to prevent at least one of a fluid or particulates from passing through the bore of the enclosure to the processing unit housed within the enclosure. The shaft of the screw is at least partially surrounded by the washer, the EMI shielding element, and the seal when the shaft of the screw is inserted into the bore of the enclosure. The washer, the seal, the EMI shielding element, and the screw forms the spring screw mounted assembly.

Any of the aspects herein, further comprising positioning a spring operable to provide a force against the enclosure. The shaft of the screw is operable to be inserted through the spring and into the bore of the enclosure. The spring is positioned between the head of the screw and the washer. The washer is operable to transmit the force applied by the spring against at least a portion of the enclosure. The washer, the seal, the EMI shielding element, the spring, and the screw forms the spring screw mounted assembly.

Any of the aspects herein, wherein the washer and the EMI shielding element are operable to fit within a first cut-out having a first diameter and a first depth in a surface in the enclosure. The seal is operable to fit within a second cut-out having a second diameter that is smaller than the first diameter and a second depth that is lower than the first depth in the surface of the enclosure.

The preceding is a simplified summary of the disclosure to provide an understanding of some aspects of the disclosure. This summary is neither an extensive nor exhaustive overview of the disclosure and its various aspects, embodiments, and configurations. It is intended neither to identify key or critical elements of the disclosure nor to delineate the scope of the disclosure but to present selected concepts of the disclosure in a simplified form as an introduction to the more detailed description presented below. As will be appreciated, other aspects, embodiments, and configurations of the disclosure are possible utilizing, alone or in combination, one or more of the features set forth above or described in detail below.

Numerous additional features and advantages of the present disclosure will become apparent to those skilled in the art upon consideration of the embodiment descriptions provided hereinbelow.

### BRIEF DESCRIPTION OF THE DRAWINGS

FIG. 1 shows a perspective section view of an electronics package including a spring screw mounted assembly with a spring-loaded screw and electromagnetic interference shielding and sealing aspects, in accordance with embodiments of the present disclosure.

FIG. 2 shows a perspective section view of an electronics package including multiple spring screw mounted assemblies, each assembly with a spring-loaded screw and electromagnetic interference shielding and sealing aspects, in accordance with embodiments of the present disclosure.

FIG. 3 shows an elevation section view of an electronics package including multiple spring screw mounted assemblies, each assembly with a spring-loaded screw and electromagnetic interference shielding and sealing aspects, in accordance with embodiments of the present disclosure.

FIG. 4 is a flow diagram of a method or process for assembling an electronics package including at least one spring screw mounted assembly, each assembly with a spring-loaded screw and electromagnetic interference shielding and sealing aspects, in accordance with embodiments of the present disclosure.

FIG. 5 is a flow diagram of a method or process for disassembling an electronics package including at least one spring screw mounted assembly, each assembly with a spring-loaded screw and electromagnetic interference shielding and sealing aspects, in accordance with embodiments of the present disclosure.

### DETAILED DESCRIPTION

Embodiments of the present disclosure will be described in connection with electronic packaging, and in some embodiments, the construction, structure, and arrangement of elements making up an electronics package such as a spring screw mounted assembly including electromagnetic interference shielding and sealing aspects.

In some embodiments, the present disclosure describes a spring screw mounted assembly including an enclosure (e.g., chassis, housing, casing, or the like) that houses one or multiple processing units and is held together at least in part by one or multiple spring-loaded screws. For example, the one or multiple processing units may include, but are not limited to, microprocessors, chips, integrated circuits, system on chips (SOCs), or the like on a printed circuit board (PCB) or other circuit substrate. For instance, an SOC may include a processing unit with all necessary electronic circuits and parts for a given system, such as computer chips, on a single integrated circuit. In some embodiments, the electronics package may be used in a vehicle, for example, to assist in autonomous handling and driving of the vehicle, where the SOCs provide computations and/or other features for operating the vehicle. While described in the context of a vehicle, however, it is noted the electronics package described herein may be used for other purposes without departing from the scope of the present disclosure. Additionally, the spring screw mounted assemblies described herein may be used for any given electronics package that includes one or multiple processing units that requires at least a cooling system including, but not limited to, contact with a heatsink or heatsink assembly to operate efficiently.

Thermal management of processing units has existed for some time. That is, most electronic devices or electronics packages generate heat while in use (e.g., typically generated by the flow of electric current through one or more resistive elements and/or components such as the processing units in the electronic devices or electronics packages). When the heat generated by these elements and/or components is not efficiently removed, the temperatures of an electronic device can exceed a normal operating range, where operating the electronic device at temperatures outside of the normal operating range (even periodically) can cause premature failures in the electronic device and/or result in shorter life spans of components in the electronic device. The efficient thermal management of electronic components and devices generally requires one or more cooling systems/elements. For example, the heat generated may be routed to, and/or dissipated, into a surrounding environment.

As described herein, a spring screw mounted assembly is provided which includes spring-loaded screws designed to thermally connect one or multiple processing units (e.g., SOCs or SOC processors) in an electronics package to a cooling device of the electronics package such as a heatsink. In some embodiments, the electronics package includes thermal interfacing or a thermal interface material (TIM) such as thermal grease, thermal paste, and/or one or multiple thermal transfer devices or pads (e.g., “spreader” pads, heat spreaders, cooling pads, etc.) positioned between a surface of the enclosure (e.g., an interior surface) and the processing units housed within the enclosure. The spring-loaded screws are operable to cause an accurate controllable load to the processing unit against the heatsink, ensuring a sufficient or minimum thermal contact between the enclosure and the processing units including via intermediary thermal interfacing. For purposes of the present disclosure, “thermal contact” includes actual physical contact between components or a gap that allows for sufficient thermal transfer to occur via thermal interfacing or TIM positioned within the gap and between the components.

In select environments, such as where the electronics package is installed within a vehicle that is operable in dust, dirt, mud, rain, or snow conditions, the holes through a portion of the enclosure into which the spring-loaded screw extend and engage with other portions of the enclosure are susceptible to particulate or fluid leakage. In some embodiments, the spring screw mounted assembly may include a seal or sealant (e.g., such as a gasket, or the like) proximate to a hole within a first portion of the enclosure through which the screw passes to engage a stiffener while positioning the processing unit in between the enclosure and the stiffener.

In addition, where the electronics package is installed in a vehicle, the electronics package and/or the components housed within may be susceptible to electromagnetic interference (EMI) from surrounding components within the vehicle and/or from other sources within a surrounding environment. In some embodiments, the spring screw mounted assembly may include a shielding element such as EMI shielding operable to protect the internal components (e.g., processing units, or the like) housed within the enclosure from the electromagnetic interference.

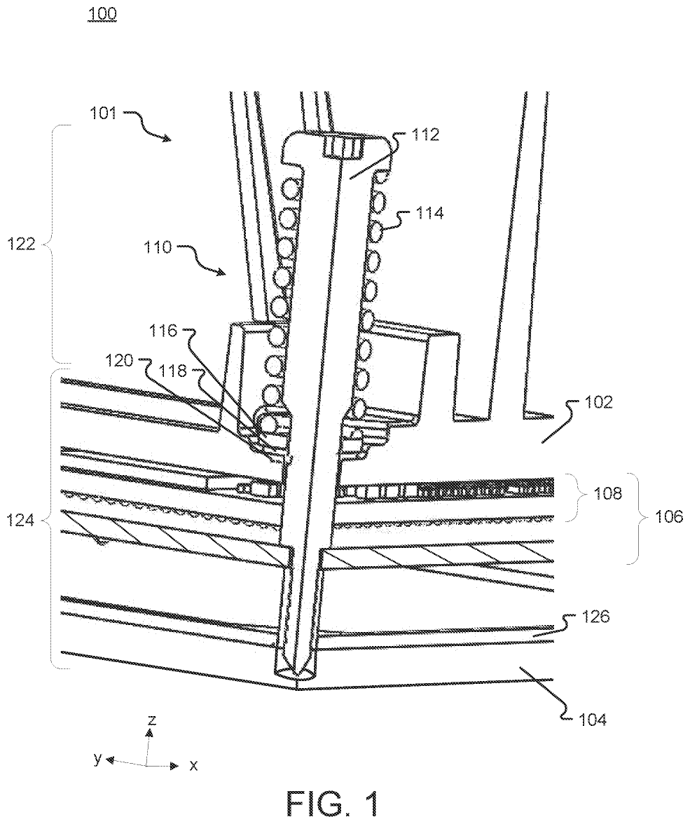

With the installation of the springs, the spring screw mounted assembly applies a controllably accurate pressure between hot processing units and the heatsink. Also, a stiffener on the other size of the processing units helps to apply uniform load all around the processing unit and prevent strain critical spots while keeping a minimum space between the processing unit and the heatsink. It is noted that an exemplary z-direction for the spring screw mounted assembly is illustrated in FIGS. 1-3.

In some embodiments, an electronic component assembly or electronics package includes a spring screw mounted assembly with a seal operable to prevent fluid or particulate leakage into the electronic component assembly, where the seal is compressed into a groove within an upper housing. The spring screw mounted assembly also includes EMI shielding (or an EMI shield) positioned within the same or another groove within the upper housing to allow for an electrical connection between screw and the enclosure. The spring screw mounted assembly further includes a screw that passes through the EMI shielding and the seal. The seal is operable to conform to the screw once the screw passes through to prevent fluid or particulate leakage into the electronic component assembly. A washer is positioned between the EMI shielding and a head of the screw and/or a spring through which the screw passes, to distribute forces from the head of the screw and/or the spring through which the screw passes relative to the EMI shielding and/or the seal. In general, the washer may be directly or indirectly (e.g., via the EMI shielding) in contact with the enclosure, to distribute forces from the spring to the enclosure and around the EMI shielding and/or the seal and provide the electrical connection.

Embodiments of the present disclosure provide technical solutions to one or more of the problems of (1) providing sufficient protection against fluid or particulate leakage into an electronic component assembly with a seal, and (2) providing sufficient protection or shielding of the components within the electronic component assembly from electromagnetic emission or electromagnetic interference EMI. The sealing gasket may prevent fluid or particulate leakage into the electronic component assembly from external sources. The EMI shielding may prevent EMI at the internal components within the electronic component assembly from external sources, and/or prevent the internal components from creating EMI that propagates outward and interferes with other external components.

Turning now to FIG. 1, a perspective section view 100 of an electronics package 101 is provided, in accordance with embodiments of the present disclosure. In some embodiments, the electronics package 101 may be designed to provide functions to and/or assist in operating a vehicle. For example, the electronics package 101 may be a computer module for use in a vehicle. In some examples, the functions provided by the electronics package 101 may include critical functions for the vehicle, such as autonomous driving operations, navigation, RADAR, vehicle controls, communications (e.g., vehicle-to-vehicle (V2V) or vehicle-to-everything (V2X) communications), etc. Additionally, the vehicle described herein may include any conveyance or model of a conveyance, where the conveyance was designed for the purpose of moving one or more tangible objects, such as people, animals, cargo, and the like. The term “vehicle” does not require that a conveyance moves or is capable of movement. Typical vehicles may include, but are in no way limited to, electric vehicles, cars, trucks, motorcycles, busses, automobiles, bicycles, scooters, paved or unpaved surface conveyances, trains, railed conveyances, boats, ships, marine conveyances, submarine conveyances, airplanes, space craft, flying machines, human-powered conveyances, and the like.

As described herein, the electronics package 101 may include a first or upper housing 102. The electronics package 101 may include a second or lower housing 104. The electronics package 101 may include an internal volume or package envelope 106 defined between the upper housing 102 and the lower housing 104.

In some embodiments, one or multiple processing units 108 may be positioned within the package envelope 106. It is noted the processing units may be referred to as SOCs or integrated circuits or may include SOCs. SOCs may be microchips with all necessary electronic circuits and parts for a given system, such as computer chips or chips that enable/provide a system in a vehicle, on a single integrated circuit. For example, the SOCs may perform computations and/or provide other features for operating the vehicle. In some examples, the multiple SOCs may operate together (e.g., or in subsets) to provide features for operating the vehicle, and/or individual SOCs may provide separate features for operating the vehicle. While described in the context of a vehicle, the electronics package 101 described herein may be used for providing other purposes and in other contexts not explicitly described herein.

It is noted herein the processing units 108 may be configured in one or more subassemblies within the package envelope 106, where each subassembly includes one or multiple processing units (e.g., microprocessors, chips, integrated circuits, system on chips (SOCs), or the like) on a printed circuit board (PCB) or other circuit substrate. In some examples, the one or more subassemblies may be parts of respective daughter cards and/or a same daughter card that are attached and electrically coupled to a main PCB or motherboard (e.g., as illustrated by the banding in FIG. 1). The daughter card(s) may provide complementary or supplementary functions to the main PCB or motherboard stored in the electronics package 101. For example, the daughter card(s) may be types of circuit boards that plug in or are attached to a motherboard or similar expansion card (e.g., the main PCB) to extend features and services of the motherboard or similar expansion card. That is, the daughter card may complement or supplement an existing functionality of a motherboard or an expansion card. The daughter card(s) (and/or the main PCB) may, in part, provide a function for a vehicle (e.g., electrical vehicle) but is not limited to such examples. In addition, the daughter card(s) may require high amounts of power to provide the complementary/supplementary functions, which may result in generated heat that must be dissipated to prevent temperatures of the electronics package 101 from exceeding normal operating temperatures and, thereby, lessening the chances of premature failures of the electronics package 101 and/or components within the electronics package 101. Further, the daughter card(s) may be at the same or different heights within the package envelopes 106, such that additional care has to be taken to ensure sufficient or minimum thermal contact between the processing units 108 and the upper housing 102.

Depending on the arrangement, orientation, and/or configuration of the processing units 108 within the package envelope 106, is noted herein that the various discussion related to the interfacing between the processing units 108 and the upper housing 102 throughout the present disclosure may be similarly understood to read on the processing units 108 and the lower housing 104, without departing from the scope of the present disclosure. Although not explicitly shown in the various Figs., it is noted the package envelope 106 may include, but is in no way limited to, a plurality of other components that fit between or around the other components described herein. For example, the electronics package 101 may include one or more gaskets, o-rings, thermal spacers, clamps, and/or other components between the upper housing 102 and the lower housing 104, between the processing units 108 and the upper housing 102, between the processing units 108 and the lower housing 104, between processing units 108, and the like.

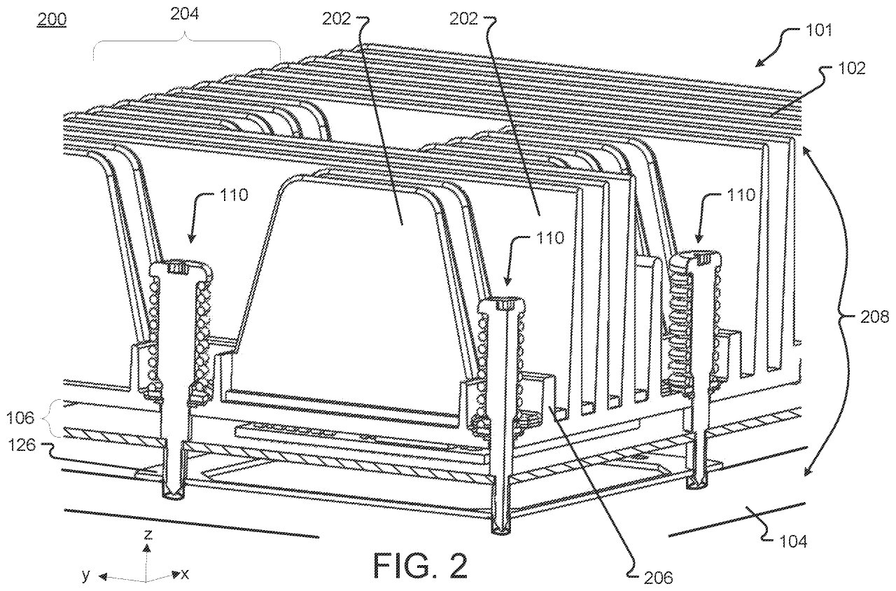

As described in greater detail herein with reference to FIGS. 2-5, the electronics package 101 may include a spring screw mounted assembly 110. In embodiments, the spring screw mounted assembly 110 may include one or more of a screw 112, a spring 114, a washer 116, electromagnetic interference (EMI) shielding 118 (or EMI shielding element 118), and/or a seal 120 (or sealing element 120). For example, at least a first portion of the screw 122 is positioned exterior to the upper housing 102, and at least a second portion of the screw 124 is operable to be inserted into the upper housing 102. For instance, the at least a second portion of the screw 124 may engage with the upper housing 102, a stiffener 126, and/or components housed within the electronics package 101 to secure the electronics package 101 together. Although not shown, it is noted that the upper housing 102 and the lower housing 104 may be coupled together either directly (e.g., with fasteners) or indirectly (e.g., with both coupled to an intermediate component or frame portion, the stiffener 126, or the like), without departing from the scope of the present disclosure.

FIG. 2 depicts a section perspective view 200 of the electronics package 101, in accordance with embodiments of the present disclosure. In some examples, the perspective section view 200 as described with reference to FIG. 2 may implement aspects of or may be implemented by aspects of FIG. 1. For example, the section perspective view 200 of the electronics package 101 may be a view of different components included in the electronics package 101 as described with reference to FIG. 1.

While in use, the electronics package 101 may generate heat, for example, typically generated by the flow of electric current through one or more resistive elements and/or components of the electronics package 101, such as the processing units described above. If the heat generated in the electronics package 101 (e.g., via the processing units) is not efficiently removed, temperatures of the electronics package 101 may exceed a normal operating range. In some examples, operating the electronics package 101 at temperatures outside of the normal operating range (even periodically) can cause premature failures in the electronics package 101 and/or result in shorter life spans of components in the electronics package 101.

The upper housing 102 and/or the lower housing 104 of the electronics package 101 may include cooling structures 202. For example, the cooling structures 202 may include, but in no way limited to, heatsink fins, or the like. It is noted that the cooling structures 202 are not limited to the shapes and/or configuration as shown in FIG. 2, and that other shapes and/or configurations for the cooling structures 202 are possible without departing from the scope of the present disclosure.

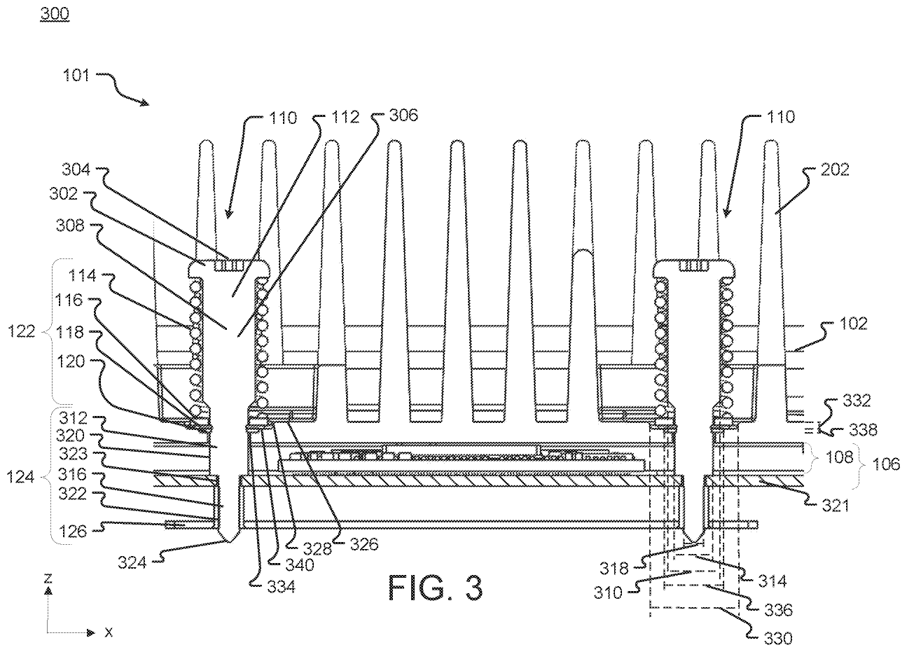

The upper housing 102 and/or the lower housing 104 of the electronics package 101 may include areas 204 without the cooling structures 202, such as where the spring screw mounted assemblies 110 are positioned on the electronics package 101. In embodiments, the areas 204 include raised structures 206 that are proximate to the spring screw mounted assemblies 110 and/or into which the spring screw mounted assemblies 110 are inserted. For example, as described in detail herein with respect to FIG. 3, the raised structures 206 may assist in retaining select components of the spring screw mounted assembly 110 at the defined position on the electronics package 101. It is noted, however, that the spring screw mounted assemblies 110 may be inserted into the upper housing 102 and/or the lower housing 104 at a substantially flat portion of a surface of the respective housing, such that the raised structures 206 are optional without departing from the scope of the present disclosure.

For purposes of the present disclosure, the combination of the upper housing 102, the lower housing 104, and the package envelope 106 may together be considered portions of an enclosure 208 of the electronics package 101.

In general, the positioning of the spring screw mounted assemblies 110 may be anywhere on the electronics package 101, so long as the spring screw mounted assemblies 110 provide an accurate controllable load to the processing unit against the heatsink to ensure sufficient or minimum thermal contact between portions of the enclosure 208 (e.g., the upper housing 102) and the processing units housed within portions of the enclosure 208 (e.g., within the package envelope 106) to dissipate heat from the processing units 108 via the cooling structures 202. Where thermal interfacing is positioned between the processing units 108 and the enclosure 208, the positioning of the spring screw mounted assemblies 110 should also prevent the movement of the thermal interfacing, and generally ensure sufficient or minimum thermal contact between the enclosure 208, the thermal interfacing, and the processing units 108. In this regard, the positioning of the spring screw mounted assemblies 110 relative to the cooling structures 202 is provided only for illustration, and should not be considered limiting for purposes of the present disclosure.

FIG. 3 depicts an elevation section view 300 of the electronics package 101 in an assembled state, in accordance with embodiments of the present disclosure. In some examples, the elevation section view 300 as described with reference to FIG. 3 may implement aspects of or may be implemented by aspects of FIGS. 1 and 2. For example, the elevation section view 300 of the electronics package 101 may be a view of the electronics package 101 as described with reference to FIG. 1 and/or FIG. 2.

It is noted that the following discussion is generally directed to one spring screw mounted assembly 110, but that it should be understood can be extended to some or all of a plurality of spring screw mounted assemblies 110 of the electronics package 101 (e.g., as illustrated in FIGS. 2 and 3), without departing from the scope of the present disclosure. It is noted herein that the lower housing 104 is not shown in FIG. 3 for purposes of clarity only, with the absence of the lower housing 104 not intended to be limiting on the present disclosure.

The screw 112 may include a head 302 at a proximal end. The head 302 (and/or the screw 112 in general) may include one or more tool engagement features 304. The tool engagement feature 304 may be operable to receive a tool and transfer a force imparted upon the tool to the screw 112 when the spring screw mounted assembly 110 is installed in the electronics package 101. For example, the tool engagement feature 304 may be configured to receive an exteriorly-received tool (e.g., a surface or set of surfaces operable to engage with a wrench, socket, or the like). By way of another example, the tool engagement feature 304 may be configured to receive an interiorly-received tool (e.g., a slot, bore, or other aperture operable to engage with a hex wrench, a screwdriver or bit including a flat, Philips, square, or Torx or star end, or the like).

The screw 112 may include a shaft 306 with one or more sections along an axial length (e.g., in a z-direction) of the screw 112. In one non-limiting example, the shaft 306 may be a single shaft section 308 with a single diameter 310. The shaft section 308 may form both the first portion 122 and the second portion 124 of the screw 112.

In a second non-limiting example, the shaft may have multiple sections including, but is no way limited to, a first shaft section 308 with a first shaft diameter 310, a second shaft section 312 with a second shaft diameter 314, a third shaft section 316 with a third shaft diameter 318, . . . up to an N number of shaft sections with an N number of shaft diameters. For instance, some or all of the first shaft section 308 may form the first portion 122 of the screw 112, while some or all of the second shaft section 312 and the third shaft section 316 may form the second portion 124 of the screw 112. It is noted herein, however, that the first shaft section 308 and the second shaft section 312 may be the same diameter, and/or the second shaft section 312 and the third shaft section 316 may be the same diameter, without departing from the scope of the present disclosure.

It is noted there may be one or more transition regions between the various shaft sections 308, 312, 316. The one or more transition regions may create an abrupt change in diameter, a constant-slope change in diameter, a change in diameter that is contoured to conform to an arcuate shape between the adjacent regions, or a combination thereof. For example, a transition region may connect the first shaft section 308 with the second shaft section 312, where the transition region includes an exterior sidewall with a substantially constant slope. By way of another example, a transition region may connect the second shaft section 312 with the third shaft section 316, where the transition includes an abrupt change in diameter. These examples are provided only for illustration, however, and are not intended to be limiting on the present disclosure.

In the second non-limiting example, the first shaft section 308 with the first shaft diameter 310 is operable to receive the spring 114, with the first shaft diameter 310 being selected to accommodate the size of available spring 114 that is chosen based on a required load. In addition, the second shaft section 312 may enter or pass through a first bore 320 with a diameter that is substantially similar to, or larger than, the diameter 314 of the second shaft section 312 to allow for smooth or non-interfered passage of the second shaft section 312. In some instances, the second shaft section 312 may come into contact with a surface of a PCB within the package envelope 106.

Also in the second non-limiting example, the third shaft section 316 may enter or pass through a second bore 322 with a diameter that is substantially similar to, or larger than, the diameter 318 of the second shaft section 316 to allow for smooth or non-interfered passage of the second shaft section 316. Alternatively, the third shaft section 316 may pass through a second bore 322 with a diameter that is smaller than the diameter 318 of the second shaft section 316, resulting in threading the third shaft section 316 into the second bore 322. In some instances, the first bore 320 is on the upper housing 102 and the second bore 322 is on the stiffener 126, with threading in the bore 322 that corresponds to threading on the third shaft section 316 to tighten the screw 112 to the stiffener 126.

It is noted herein that the bore 320 may be considered a bore within the upper housing 102 (or generally the enclosure 208). In addition, it is noted herein that the bore 322 may be considered a bore through at least one of a PCB or other PCB, and/or the stiffener 126 (e.g., through a standoff of the stiffener 126). In some examples, a PCB 321 (e.g., as illustrated by the banding in FIG. 3) includes an aperture 323 that at least partially forms the bore 322, or alternatively is prior to and leads to the bore 322 from the bore 320. The aperture 323 may be within the surface of the PCB 321 with which the second shaft section 312 comes into contact, and the aperture 323 may be operable to receive the third shaft section 316. It is noted that the PCB 321 may be the same as or separate from the one or more processing units 108. In some instances, the one or more processing units 108 include daughter cards that are in communication with the main PCB 321 (e.g., a motherboard or mother card).

In general, the various shaft diameters may be same or different. In the second non-limiting example as discussed above, the first shaft diameter 310 is larger than the second shaft diameter 314, and the second shaft diameter 314 is larger than the third shaft diameter 318. It is noted, however, that this example is only provided for purposes of illustration, as is not to be interpreted as limiting.

Although not shown, it should be understood that the second shaft section 312 may include threading that is complementary to threading in the first bore 320. Alternatively, where there is only the single shaft section 308, then at least a portion of the single shaft section 308 may include threading that is complementary to a corresponding bore in the electronics package 101.

It is noted that a portion of the first bore 320 and/or the second bore 322 may be formed by the stiffener 126. In embodiments, the stiffener 126 may include a standoff that spaces or separates layers within the package envelope 106 and/or spaces the upper housing 102 from the lower housing 104 (e.g., as shown in FIG. 1). In embodiments, the stiffener 126 may assist in distributing load under the processing units 108 within other layers of the package envelope 106.

In addition, it is noted the first bore 320 may pass through the upper housing 102 and/or one or more layers housed within the package envelope 106. Further, it is noted the second bore 322 may pass through one or more layers housed within the package envelope 106 and/or be within the stiffener 126.

The screw 112 may include a tip 324 at a distal end. The tip 324 may be flat or may be pointed, without departing from the scope of the present disclosure. In some examples, the tip 324 may be positioned within the stiffener 126 and/or within a groove or cavity within the lower housing 104 (e.g., as shown in FIG. 1) when the screw 112 is inserted into the electronics package 101.

One or more of the shaft sections 308, 312, 316 may be passed through and/or be positioned within the coils the spring 114 when the screw 112 is inserted into the electronics package 101. The spring 114 may be configured to exert a directional force on the washer 116 and/or the head 302 of the screw 112 when the electronics package 101 is fully assembled, such that the upper housing 102 is moved to come into thermal contact with processing units 108 within the package envelope 106 of the electronics package 101. Subsequently, the thermal energy produced by the processing units 108 of the electronics package 101 may be transferred through the upper housing 102 and the cooling structures 202 based on the directional force exerted by the spring 114. For example, the directional force exerted by the spring 114 is designed to move the upper housing 102 towards the processing units 108 to enable thermal contact, where the heat generated by the processing units 108 is absorbed by the upper housing 102 and distributed by the cooling structures 202.

The spring 114 may exert a force either directly or indirectly on the head 302 of the screw 112 and the upper housing 302. For example, the spring 114 may exert a force on the head 302 and the washer 116, where the washer 116 transfers the force to the upper housing 302. In this example, the washer 116 provides a uniform load from the spring 114 to the EMI shielding 118 and to the upper housing 102. Also, the washer 116 provides increased electrical contact between the spring 114 and the EMI shielding 118, while preventing damage to the EMI shielding 118 that may be caused by the spring 114.

In embodiments, the washer 116 may be fabricated from a material that is able to withstand the forces applied on the washer 116 by the spring 114. For example, the washer may be fabricated from a material including, but in no way limited to, a metal. In some examples, the washer 116 may be made of steel, zinc-coated steel, stainless steel, copper, brass, titanium, aluminum, or an alloy including any of the previous metals. In general, the washer 116 may be fabricated from any material with sufficient electrical conductive properties to provide contact between the EMI shielding 118, the screw 112, the spring 114, and the upper housing 102 (and thus the enclosure 208).

The EMI shielding 118 may be fabricated from a foam material or other biasable or resilient material. The EMI shielding 118 should have properties that are sufficient to shield internal components within the electronics package 101 from electromagnetic interference that may pass through the bores 322 and/or 320 radiating from external components, and/or shield external components from electromagnetic interference that may pass through the bores 322 and/or 320 radiating from the internal components within the electronics package 101. The EMI shielding 118 may be at least partially compressible due to an applied force from the washer 116, the seal 120, and/or one or more surfaces of the upper housing 102.

The seal 120 may be fabricated from a material including, but in no way limited to, a biasable or resilient plastic or a biasable or resilient elastomer (or elastic polymer including thermosets and thermoplastics) such as a rubber. The seal 120 may be configured to ensure fluids such as air or water (e.g., rain or snow) and particulates (e.g., dust, dirt, or mud). The seal 120 may be at least partially compressible due to an applied force from the EMI shielding 118, and/or one or more surfaces of the upper housing 102.

The washer 116, the EMI shielding 118, and/or the seal 120 may be seated within a cut-out in a surface 326 of the upper housing 102. For example, the surface 326 may be an upper surface proximate to the cooling structures 202, and/or a lower surface proximate to the package envelope 106.

The cut-out may have one or more diameters at one or more depths (e.g., having select heights) within a thickness of the upper housing 102, allowing for the stacking of one or more of the washer 116, the EMI shielding 118, and/or the seal 120 flush or below the surface 326 and within the body of the upper housing 102. Where there are multiple, different diameters, the cut-out may be considered a stepped cavity for purposes of the present disclosure.

In one non-limiting example, there may be multiple cut-outs including, but in no way limited to, a first cut-out 328 having a first cut-out diameter 330 and a first depth 332 in which the washer 116 and the EMI shielding element 118 is seated, and a second cut-out 334 having a second cut-out diameter 336 and a second depth 338 in which the seal 120 is seated.

In general, the various cut-out diameters and/or heights may be same or different. In the non-limiting example above, the first cut-out diameter 330 is larger than the second cut-out diameter 336. This allows the EMI shielding 118 and/or the washer 116 to have a greater diameter than the seal 120, allowing the EMI shielding 118 and/or the washer 116 to make physical and electrical contact with a surface 340 that is substantially parallel to the surface 326 of the upper housing 102 and that is angled or substantially perpendicular to the axis through the screw 112, instead of being prevented from making contact by the seal 120. In addition, the second cut-out diameter 336 being smaller than the first cut-out diameter 330 assists in the sealing of the bore 320, as the seal 120 is pressed into the smaller cut-out diameter 330 of the second cut-out 334 beneath the EMI shielding 118 and washer 116 positioned within the first cut-out 328. Further, the decreasing diameters along the axial length of the screw 112 ensures that the washer 116 covers and/or protects the EMI shielding 118, and the EMI shielding 118 similarly covers and/or protects the seal 120. It is noted, however, that this example is only provided for purposes of illustration, as is not to be interpreted as limiting of the present disclosure. Also in the second non-limiting example, a height of the first cut-out depth 332 may be greater than a height of the second cut-out depth 338.

Also in the non-limiting example above, the section shaft portion 312 and the third shaft portion 316 of the screw 112 may be at least partially surrounded by the washer 116, the EMI shielding 118, and/or the seal 120 when the screw 112 is inserted into the electronics package 101. For example, one or more portions of the screw 112 may at least partially pass through inner apertures or openings of the washer 116, the EMI shielding 118, and the seal 120 when the screw 112 is inserted into the electronics package 101. The washer 116 and the EMI shielding 118 may rest within the first cut-out 328, and the seal 120 may be press-fit within the second cut-out 334. Forces exerted on the EMI shielding 118 by the washer 116 (e.g., which transfers the force from the spring 114) may cause the EMI shielding 118 to slightly expand outward, being compressible. The seal 120 may also be dimensioned with an inner diameter that is smaller than the second shaft diameter 314 of the second shaft portion 312, such that the seal 120 additionally forms an interference fit with the screw 112. It is noted that the EMI shielding 118 may additionally be dimensioned with an inner diameter that is smaller than the second shaft diameter 314 of the second shaft portion 312, such that the EMI shielding 118 also forms an interference fit with the screw 112.

In some instances, the thickness of the seal 120 is greater than the depth 338 of the second cut-out 334. Compression of the seal 120 causes a top surface of the seal 120 to become flush with the surface 340 during the expansion of the seal 120 to fill the second cut-out 334 and the distribution of the additional material provided by the increased thickness of the seal 120. In addition, the EMI shielding 118 may be of a thickness that is able to expand and at least partially fill the first cut-out 328 which a force is applied on the EMI shielding 118 by the washer 116 (e.g., as transferred from the spring 114).

It is noted that the cut-outs 328, 334 and/or the washer 116, EMI shielding 118, and seal 120 may be substantially circular in a planar cross-section, or alternatively may be any polygonal shape in the planar cross-section without departing from the scope of the present disclosure. In addition, although embodiments are directed to the washer 116 and the EMI shielding 118 being in the same cut-out 328, it is noted that the washer 116 and the EMI shielding 118 may have different respective cut-outs, without departing from the scope of the present disclosure.

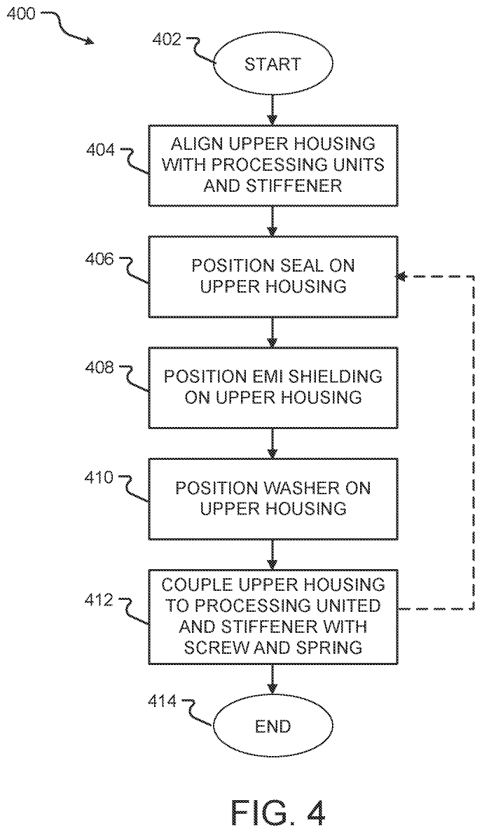

FIG. 4 depicts a flow diagram of a method or process 400 for assembling the electronics package 101, in accordance with embodiments of the present disclosure. For example, the method or process 400 may be used for forming and assembling the electronics package 101 that at least includes the spring screw mounted assembly 110 as described herein and with reference to FIGS. 1-3. While a general order for the steps of the method or process 400 is shown in FIG. 4, the method or process 400 can include more or fewer steps or can arrange the order of the steps differently (including simultaneously, substantially simultaneously, or sequentially) than those shown in FIG. 4. Generally, the method or process 400 starts with a START operation at step 402 and ends with an END operation at step 414. The method or process 400 can be, but is not limited to being, executed as a set of computer-executable instructions executed by an assembly machine (e.g., robotic assembly system, automation assembly system, computer aided drafting (CAD) machine, etc.) and encoded or stored on a computer readable medium. Hereinafter, the method or process 400 shall be explained with reference to the components, devices, assemblies, environments, etc. described in conjunction with FIGS. 1-3.

In a step 404, an upper housing 102 is aligned with processing units 108 and a stiffener 126. The processing units 108 may be positioned between the upper housing 102 and the stiffener 126. It is noted that the upper housing 102, the processing units 108, and/or the stiffener 126 may include one or more assistive components such as, but in no way limited to, alignment grooves and pins or the like to increase the likelihood of correct alignment. Although not shown, additional gaskets or seals may be positioned between adjacent flanges or mating surfaces of the upper housing 102 and the stiffener 126 during alignment.

In a step 406, a seal 120 is positioned on the upper housing 102. In one non-limiting example, the seal 120 may be press-fit into the second cut-out 334 to ensure proper sealing against fluid or particulate leakage proximate to the bores 322 and/or 320 occurs.

In a step 408, EMI shielding 118 is positioned on the upper housing 102. In one non-limiting example, the EMI shielding 118 may be positioned on the seal 120 and in the first cut-out 328. Respective inner apertures or openings within the EMI shielding 118 and the seal 120 may be coaxially-aligned.

In a step 410, a washer 116 is positioned on the upper housing 102. In one non-limiting example, the washer 116 may be positioned on the EMI shielding 118 and in the first cut-out 328. Respective inner apertures or openings within the washer 116, the EMI shielding 118, and the seal 120 may be coaxially-aligned.

Although steps 406, 408, 410 are described as the stacking of the seal 120, the EMI shielding 118, and the washer 116 on an upper surface of the upper housing 102, it is noted the seal 120, the EMI shielding 118, and the washer 116 may instead be stacked or positioned within cut-outs in a lower surface of the upper housing 102. For example, prior to alignment with the processing units 108 and the stiffener 126, the upper housing 102 may be turned over and the washer 116 and the EMI shielding 118 may be positioned in the lower surface before the seal 120 is press-fit into the lower surface. In this regard (and in general), the step 404 including alignment of the upper housing 102 with the processing units 108 and the lower housing 104 may occur after steps 406, 408, 410, without departing from the scope of the present disclosure.

In a step 412, the upper housing 102, the processing units 108, and the stiffener 126 are coupled with a screw 112 and spring 114. The screw 112 is inserted into the spring 114 and then through the washer 116, the EMI shielding 118, and the seal 120 before entering into the bores 322 and/or 320 of the electronics package 101 (e.g., within the upper housing 102, the processing units 108, and the stiffener 126). The screw 112 is turned (e.g., via the tool engagement feature 304) until a desired or pre-determined torque value is achieved. This allows for an accurate controllable load to be exerted and maintained at all times by the spring 114 on the head 302 of the screw 112 and on the washer 116, ensuring the sufficient or minimum thermal contact occurs between the processing units 108 and the upper housing 102. It is noted that the step of coupling the upper housing 102 and the stiffener 126 with a screw 112 and spring 144 may include substeps such as, but in no way limited to, positioning a spring operable to provide a force against the upper housing 102 or enclosure 208, and inserting a screw 112 into the spring 114 and into a bore of the upper housing 102 or enclosure 208.

It is noted that installing the screw 112 and the spring 114 completes the spring screw mounted assembly 110 with the washer 116, the EMI shielding 118, and the seal 120. Steps 406, 408, 410, and 412 may then be repeated as necessary for the additional spring screw mounted assemblies 110 to be installed in the electronics package 101.

It is noted that the method or process 400 may include one or more steps directed to coupling the upper housing 102 and/or the stiffener 126 (e.g., depending on the build on the electronics package 101) to the lower housing 104, without departing from the scope of the present disclosure. For example, the lower housing 104 may be coupled to the upper housing 102 at any point before, between, or after steps 406, 408, 410, and 412. For instance, the lower housing 104 may be coupled to the upper housing 102 after step 412 is completed.

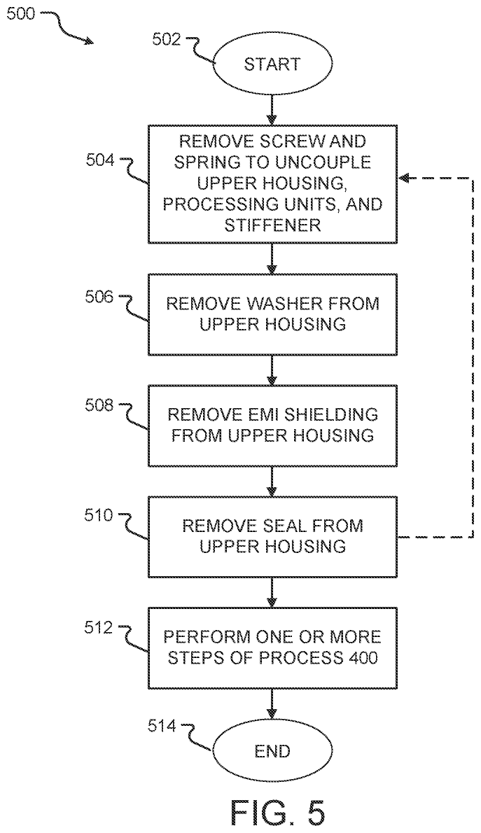

FIG. 5 depicts a flow diagram of a method or process 500 for assembling the electronics package 101, in accordance with embodiments of the present disclosure. For example, the method or process 500 may be used for disassembling the electronics package 101 that at least includes the spring screw mounted assembly 110 as described herein and with reference to FIGS. 1-3 and the method or process 400 of FIG. 4. While a general order for the steps of the method or process 500 is shown in FIG. 5, the method or process 500 can include more or fewer steps or can arrange the order of the steps differently (including simultaneously, substantially simultaneously, or sequentially) than those shown in FIG. 5. Generally, the method or process 500 starts with a START operation at step 502 and ends with an END operation at step 514. The method or process 500 can be, but is not limited to being, executed as a set of computer-executable instructions executed by an assembly machine (e.g., robotic assembly system, automation assembly system, computer aided drafting (CAD) machine, etc.) and encoded or stored on a computer readable medium. Hereinafter, the method or process 500 shall be explained with reference to the components, devices, assemblies, environments, etc. described in conjunction with FIGS. 1-3 and the method or process of FIG. 4.

In a step 504, a screw 112 and a spring 114 are removed to uncouple an upper housing 102, the processing units 108, and the stiffener 126. Uncoupling the upper housing 102 allows for access to the processing units 108 positioned in the package envelope 106 within the upper housing 102 and the stiffener 126 (e.g., such as for review, repair, replacement, or the like). It is noted that removing the screw 112 may break an interference fit between the screw 112 and a seal 120. Although not shown, additional gaskets or seals may be positioned between adjacent flanges or mating surfaces of the upper housing 102 and the lower housing 104, which may need to be removed.

In a step 506, a washer 116 is removed from the upper housing 102. The washer 116 may be removed from a first cut-out 328.

In a step 508, EMI shielding 118 is removed from the upper housing 102. The EMI shielding may be removed from the first cut-out 328.

In a step 510, the seal 120 is removed from the upper housing 102. The seal 120 may be removed from a second cut-out 334. It is noted that the seal 120 may be press-fit into the second cut-out 334.

It is noted that removing the screw 112, the spring 114, the washer 116, the EMI shielding 118, and the seal 120 removes a spring screw mounted assembly 110 from the electronics package 101. Steps 504, 506, 508, and 510 may then be repeated as necessary to remove any additional spring screw mounted assemblies 110 from the electronics package 101.

In a step 512, one or more steps of the method or process 400 are performed to re-assemble the electronics package 101. It is noted that some components (e.g., the EMI shielding 118 and/or the seal 120) may need to be replaced, whereas other components (e.g., the screw 112, the spring 114, the washer 116, and/or the EMI shielding 118) may be re-used during reassembly.

It is noted that the method or process 500 may include one or more steps directed to uncoupling the upper housing 102 and/or the stiffener 126 (e.g., depending on the build on the electronics package 101) from the lower housing 104, without departing from the scope of the present disclosure. For example, the lower housing 104 may be uncoupled from the upper housing 102 at any point before, between, or after steps 504, 506, 508, and 510. For instance, the lower housing 104 may be uncoupled from the upper housing 102 before step 504 is completed.

Although the FIGS. illustrate an exemplary set of coordinate axes, it is noted that the axes may be oriented differently without departing from the scope of the present disclosure. For example, the axes may reflect where the electronics package 101 is oriented in a vertical, substantially vertical, angled, substantially horizontal, or horizontal manner when installed and used in a particular environment (e.g., such as within a vehicle). In general, the axes as provided in the Figs. are included only to clarify select aspects of the stacked nature of the spring screw mounted assembly 110, and are not intended to be otherwise limiting.

The exemplary systems and methods of this disclosure have been described in relation to electronic packaging and the EMI shielding, sealing against fluids or particulates, and thermal control of sealed electronics such as processing units. However, to avoid unnecessarily obscuring the present disclosure, the preceding description omits a number of known structures and devices. This omission is not to be construed as a limitation of the scope of the claimed disclosure. Specific details are set forth to provide an understanding of the present disclosure. It should, however, be appreciated that the present disclosure may be practiced in a variety of ways beyond the specific detail set forth herein.

A number of variations and modifications of the disclosure can be used. It would be possible to provide for some features of the disclosure without providing others. In some embodiments, the present disclosure provides an electrical interconnection device that can be used between any electrical source and destination.

References in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in conjunction with one embodiment, it is submitted that the description of such feature, structure, or characteristic may apply to any other embodiment unless so stated and/or except as will be readily apparent to one skilled in the art from the description.

Although the present disclosure describes components and functions implemented in the embodiments with reference to particular standards and protocols, the disclosure is not limited to such standards and protocols. Other similar standards and protocols not mentioned herein are in existence and are considered to be included in the present disclosure. Moreover, the standards and protocols mentioned herein, and other similar standards and protocols not mentioned herein are periodically superseded by faster or more effective equivalents having essentially the same functions. Such replacement standards and protocols having the same functions are considered equivalents included in the present disclosure.

The present disclosure, in various embodiments, configurations, and aspects, includes components, methods, processes, systems and/or apparatus substantially as depicted and described herein, including various embodiments, subcombinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

The phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

The term “a” or “an” entity refers to one or more of that entity. As such, the terms “a” (or “an”), “one or more” and “at least one” can be used interchangeably herein. It is also to be noted that the terms “comprising”, “including”, and “having” can be used interchangeably.

The terms “determine,” “calculate,” “compute,” and variations thereof, as used herein, are used interchangeably and include any type of methodology, process, mathematical operation or technique.

What is claimed is:

1. A spring screw mounted assembly for electromagnetic interference shielding and sealing of an electronics package, the spring screw mounted assembly comprising:
a screw including a head and a shaft, wherein the shaft is operable to be inserted into a bore of an enclosure of the electronics package;
an electromagnetic interference (EMI) shielding element positioned between the head of the screw and the enclosure, wherein the EMI shielding element is operable to prevent electromagnetic interference from passing through the bore of the enclosure to a processing unit housed within the enclosure;
a seal positioned between the head of the screw and the enclosure, wherein the seal is operable to prevent at least one of a fluid or particulates from passing through the bore of the enclosure to the processing unit housed within the enclosure; and
a washer positioned between the head of the screw and the enclosure,
wherein the shaft of the screw is at least partially surrounded by the washer, the EMI shielding element, and the seal when the shaft of the screw is inserted into the bore of the enclosure.

2. The spring screw mounted assembly of claim 1, further comprising:
a spring operable to provide a force against the enclosure, wherein the shaft of the screw is operable to be inserted through the spring and into the bore of the enclosure, wherein the spring is positioned between the head of the screw and the washer, and wherein the washer is operable to transmit the force applied by the spring against at least a portion of the enclosure.

3. The spring screw mounted assembly of claim 1, wherein the EMI shielding element is positioned between the washer and the enclosure, and wherein the seal is positioned between the EMI shielding element and the enclosure.

4. The spring screw mounted assembly of claim 1, wherein the washer and the EMI shielding element are operable to fit within a first cut-out having a first diameter and a first depth in a surface in the enclosure, and
wherein the seal is operable to fit within a second cut-out having a second diameter that is smaller than the first diameter and a second depth that is lower than the first depth in the surface of the enclosure.

5. The spring screw mounted assembly of claim 1, wherein the seal is press-fit into the enclosure and operable to engage the shaft of the screw with an interference fit to prevent the at least one of a fluid or particulates from passing through the bore of the enclosure to the processing unit housed within the enclosure.

6. The spring screw mounted assembly of claim 1, wherein the washer, the EMI shielding element, and the seal include co-axially aligned apertures through which the shaft of the screw passes through when the shaft is inserted into the bore of the enclosure.

7. The spring screw mounted assembly of claim 1, wherein the shaft of the screw includes at least a first shaft section and a second shaft section.

8. The spring screw mounted assembly of claim 7, wherein the first shaft section includes a first shaft diameter that corresponds to a first bore diameter of the bore, and
wherein the second shaft section includes a second shaft diameter that is less than the first shaft diameter and that corresponds to a second bore diameter of a second bore, wherein the second bore diameter is less than the first bore diameter.

9. An electronics package, comprising:
an enclosure;
a processing unit housed within the enclosure; and
a spring screw mounted assembly for electromagnetic interference shielding and sealing, the spring screw mounted assembly comprising;
a screw including a head and a shaft, wherein the shaft is operable to be inserted into a bore of the enclosure;
an electromagnetic interference (EMI) shielding element positioned between the head of the screw and the enclosure, wherein the EMI shielding element is operable to prevent electromagnetic interference from passing through the bore of the enclosure to the processing unit;
a seal positioned between the head of the screw and the enclosure, wherein the seal is operable to prevent at least one of a fluid or particulates from passing through the bore of the enclosure to the processing unit; and
a washer positioned between the head of the screw and the enclosure,
wherein the shaft of the screw is at least partially surrounded by the washer, the EMI shielding element, and the seal when the shaft of the screw is inserted into the bore of the enclosure.

10. The electronics package of claim 9, wherein the enclosure further comprises:
a housing; and
a stiffener operable to uniformly distribute a force to the processing unit, the stiffener including threading that corresponds to threading on the shaft,
wherein the shaft is operable to be inserted into a bore of the housing into a printed circuit board (PCB), and wherein the threading on the shaft is operable to engage with the threading on the stiffener after insertion of the shaft into the bore of the housing and the PCB.

11. The electronics package of claim 10, further comprising:
a spring operable to provide the force against the housing, wherein the shaft of the screw is operable to be inserted through the spring and into the bore of the housing, wherein the spring is positioned between the head of the screw and the washer, and wherein the washer is operable to transmit the force applied by the spring against at least a portion of the housing.

12. The electronics package of claim 10, wherein the EMI shielding element is positioned between the washer and the housing, and wherein the seal is positioned between the EMI shielding element and the housing.

13. The electronics package of claim 10, wherein the washer and the EMI shielding element are operable to fit within a first cut-out having a first diameter and a first depth in a surface in the housing, and
wherein the seal is operable to fit within a second cut-out having a second diameter that is smaller than the first diameter and a second depth that is lower than the first depth in the surface of the housing.

14. The electronics package of claim 10, wherein the seal is press-fit into the housing and operable to engage the shaft of the screw with an interference fit to prevent the at least one of a fluid or particulates from passing through the bore of the housing to the processing unit.

15. The electronics package of claim 10, wherein the washer, the EMI shielding element, and the seal include co-axially aligned apertures through which the shaft of the screw passes through when the shaft is inserted into the bore of the housing.

16. The electronics package of claim 10, wherein the shaft of the screw includes at least a first shaft section and a second shaft section.

17. The electronics package of claim 10, wherein the first shaft section includes a first shaft diameter that corresponds a first section of the bore having a first bore diameter, and
wherein the second shaft section includes a second shaft diameter that is less than the first shaft diameter and that corresponds to a second section of the bore having a second bore diameter that is less than the first bore diameter.

18. A method for constructing an electronics package including a spring screw mounted assembly, the method comprising:
positioning a seal on an enclosure of the electronics package;
positioning an electromagnetic interference (EMI) shielding element on the enclosure;
positioning a washer on the enclosure; and
inserting a screw including a head and a shaft into a bore of the enclosure,
wherein the washer is positioned between the head of the screw and the enclosure,
wherein the EMI shielding element is positioned between the head of the screw and the enclosure, wherein the EMI shielding element is operable to prevent electromagnetic interference from passing through the bore of the enclosure to a processing unit housed within the enclosure,
wherein the seal is positioned between the head of the screw and the enclosure, wherein the seal is operable to prevent at least one of a fluid or particulates from passing through the bore of the enclosure to the processing unit housed within the enclosure,
wherein the shaft of the screw is at least partially surrounded by the washer, the EMI shielding element, and the seal when the shaft of the screw is inserted into the bore of the enclosure, and
wherein the washer, the seal, the EMI shielding element, and the screw forms the spring screw mounted assembly.

19. The method of claim 18, further comprising:
positioning a spring operable to provide a force against the enclosure, wherein the shaft of the screw is operable to be inserted through the spring and into the bore of the enclosure, wherein the spring is positioned between the head of the screw and the washer, wherein the washer is operable to transmit the force applied by the spring against at least a portion of the enclosure, and
wherein the washer, the seal, the EMI shielding element, the spring, and the screw forms the spring screw mounted assembly.

20. The method of claim 18, wherein the washer and the EMI shielding element are operable to fit within a first cut-out having a first diameter and a first depth in a surface in the enclosure, and
wherein the seal is operable to fit within a second cut-out having a second diameter that is smaller than the first diameter and a second depth that is lower than the first depth in the surface of the enclosure.
